(19) United States
(12) Patent Application Publication
(10) Pub. No.: US 2007/0091293 A1
(43) Pub. Date: Apr. 26, 2007

(54) Photoelectric sensor, optical module and method of producing same

(75) Inventors: Motoharu Okuno, Ayabe (JP); Makoto Sugimoto, Ayabe (JP); Shinjiro Kotani, Fukuchiyama (JP)

Correspondence Address: BEYER WEAVER LLP, P.O. BOX 70250, OAKLAND, CA, 94612-0250, US

(73) Assignee: OMRON Corporation

(21) Appl. No.: 11/527,890

(22) Filed: Sep. 26, 2006

(30) Foreign Application Priority Data
Oct. 19, 2005 (JP) 2005-304759

(51) Int. Cl. G01C 3/08; G02B 26/00

(52) U.S. Cl. 356/3.01; 359/237

(57) ABSTRACT

An optical module is formed with a semiconductor optical element sealed inside a transparent resin part and a lens unit affixed to its upper surface. The-lens unit has a lens part that is disposed facing opposite the semiconductor optical element through the transparent resin part. A planar part extends from the lens part along the upper surface of the transparent resin part. A photoelectric sensor may include such an optical module as a light projector and another such optical module as a light receiver.

This application claims priority on Japanese Patent Application 2005-304759 filed Oct. 19, 2005.

### BACKGROUND OF THE INVENTION

This invention relates to optical modules such as light projecting and receiving units of a photoelectric sensor and a method of producing such an optical module, as well as to a photoelectric sensor provided with such optical modules.

With such optical modules of a photoelectric sensor for the detection of an object, it is necessary to accurately position-match a semiconductor optical element such as a light emitting diode (LED), a laser diode (LD) or a photo diode (PD) with a lens such as a light projecting lens or a light receiving lens that is set corresponding to the semiconductor element. If this position-matching is not carried out sufficiently accurately, light being projected or received will not behave as intended and the detection of the object cannot be accomplished accurately.

A lens is normally set above a semiconductor optical element mounted to a substrate. In many situations, a lens is formed integrally with a cap attached to a case to which the substrate is affixed, as shown, for example, in Japanese Patent Publication Tokkai 10-125187.

In the case of an optical module thus structured, a high level of accuracy can be attained in the positioning of a semiconductor optical element and a lens by strictly controlling the accuracy of assembly positions between the components. For carrying out a position-matching accurately, it is also necessary to strictly control the accuracy in measurements such that the produced components are exactly of the shape according to the design.

It is not an easy matter, however, to strictly control the accuracy in measurements and the accuracy of assembly positions. In the case of an optical module with a lens integrally formed with a cap attached to a case, produced by mounting a semiconductor optical element to an intermediate substrate and sealing it without a transparent resin material to form a chip-size package (CSP) and mounting this IC package formed as CSP to a substrate to fasten the substrate to the case, for example, at least the following kinds of positional displacements must be taken into consideration:

(a) positional displacement generated when the semiconductor optical element is attached to the intermediate substrate;

(b) positional displacement of wiring pattern on the front and back surfaces at the time of production of the intermediate substrate;

(c) positional displacement generated when the IC package in the form of CSP is mounted to the substrate;

(d) positional displacement generated when the substrate is attached to the case;

(e) positional displacement of the lens when the lens is formed on the cap; and

(f) positional displacement generated when the cap is mounted to the case.

Thus, in the case of an optical module structured as explained above, very many controls of measurements and assembly controls become necessary, affecting the production cost adversely. Since there is a limit to the measurement and assembly controls, furthermore, even if the individual positional displacements may be controlled to be a minimum, it does not always result in an accurate position-matching between the semiconductor optical element and the lens, when the module is seen as a whole. Accordingly, the effective way to position-match a semiconductor optical element and a lens is to reduce as much as possible the number of components that exist between the semiconductor optical element and the lens.

From the point of view above, Japanese Patent Publication Tokkai 4-13989 disclosed an optical module having a semiconductor optical element such as an LED or an LD sealed inside a transparent resin material to form an IC package and attaching a lens directly to the surface of this IC package. In this case, since the device for adjusting an optical axis disclosed in Japanese Patent Publication Tokkai 2-188972 may be used to directly position-match the lens with respect to the semiconductor optical element, the types of positional displacement (a) through (f) described above need not be considered, and an accurate position-matching becomes possible.

In recent years, however, optical modules are coming to be required to be smaller, and semiconductor optical elements and lenses are coming to be miniaturized. Thus, the handling of these components is becoming difficult at the time of their positioning. To hold a lens itself is becoming difficult at the time of position-matching, and it is becoming extremely difficult to position-match a lens with respect to a semiconductor optical element.

Moreover, as semiconductor optical elements and lenses are made smaller, the distance between them in an optical module is necessarily becoming also smaller. Thus, if there is a positional displacement between them, the resultant variation in the behavior of light becomes much greater and there arises the problem of reduced yield.

As a further problem of the lenses becoming thinner, if an eject pin is used for removing a lens from the mold when it is being manufactured by injection molding, the eject pin is likely to penetrate and break the lens.

### SUMMARY OF THE INVENTION

It is therefore an object of this invention in view of the problems as presented above to provide an optical module for which the position-matching of its miniaturized semiconductor optical element and lens can be carried out easily, a method of producing such an optical module and a photoelectric sensor comprising such optical modules.

It is another object of this invention to provide such an optical module that can be manufactured with a high productivity although its lens is made thinner, a method of producing such an optical module and a photoelectric sensor comprising such optical modules.

An optical module according to this invention may be characterized as comprising a semiconductor optical element, a transparent resin part that seals in this semiconductor optical element and a lens unit affixed to an upper surface of the transparent resin part, wherein the lens unit includes a lens part that is disposed facing opposite the semiconductor optical element through the transparent resin part and a planar part that extends from the lens part along the upper surface of the transparent resin part. With an optical module thus structured, the position-matching of the lens part can be carried out easily and accurately with respect to the semiconductor optical element even if the lens part is made smaller or thinner because the lens part can be indirectly supported by the planar part of the lens unit.

In the above, it is preferable to form the planar part so as to completely surround the lens part and to extend from the entire circumference of the lens part because in this way the area of the principal surface of the planar part can be made wider and the lens unit can be supported more easily. It is also preferable to form the planar part so as to have guide walls on edge parts away from the lens part such that the guide walls extend and cover side surfaces that connect to the upper surface of the transparent resin part because this serves to roughly position-match the guide walls with respect to the side surfaces of the transparent resin part. When the lens unit and the transparent resin part are joined together by means of an adhesive, an excess portion of the adhesive can thus be guided towards the side surfaces of the transparent resin part by means of the planar part and the guide walls such that it can be prevented from becoming attached to the lens unit, etc.

It is also preferable in the above to form the planar part so as to include a pair of mutually oppositely extending portions from the lens part such that the guide walls extend from end parts of the mutually oppositely extending portions and so as to cover mutually opposite side surfaces that connect to the upper surface of the transparent resin part. With the planar part thus structured, the transparent resin part becomes sandwiched between the pair of guide walls and the position-matching of the lens unit becomes easier.

The thickness of the planar part perpendicular to the upper surface of the transparent resin part may preferably be 0.6 mm or greater, being equal to or less than the maximum thickness of the lens part. If the planar part is thus dimensioned, eject pins may be applied to the planar part when the lens unit is produced by injection molding and hence the optical module can be made smaller and thinner.

The thickness of the planar part perpendicular to the upper surface of the transparent resin part may preferably be less than 0.6 mm, the width of the guide wall in the direction perpendicular to the upper surface of the transparent resin part being 0.6 mm or greater. If the planar part is thus dimensioned, eject pins may be applied to the guide wall parts when the lens unit is produced by injection molding and hence the optical module can be made smaller and thinner. The thickness of the planar part perpendicular to the upper surface of the transparent resin part may preferably be made to be substantially the same as the thickness of the guide walls in the direction perpendicular to the side surfaces. If it is so made, the molten resin can circulate more smoothly when the lens unit is produced by injection molding.

The maximum thickness of the portion of the planar part on the transparent resin part in the direction perpendicular to the upper surface of the transparent resin part may preferably be made to be 1.0 mm or less such that a very thin and small optical module can be obtained.

In the above, the planar part may include a wall part protruding in opposite direction away from the transparent resin part and having an indentation at a position opposite the lens part, indenting in the direction towards the lens part such that an optical fiber has one end inserted to this indentation, being affixed to the wall part with the one end facing the lens part. With such a structure, an optical fiber can be easily attached to a lens unit and optical modules provided with an optical fiber can be produced easily and inexpensively. Moreover, the optical fiber can be easily position-matched with respect to the lens part to produce optical modules of a high quality.

In the above, the lens unit preferably comprises polycarbonate or acryl resin as principal material. With such a material, optical modules of this invention can be produced inexpensively by injection molding.

A photoelectric sensor according to one aspect of this invention may be characterized as including at least one of optical modules as described above either as a light projector or as a light receiver.

A photoelectric sensor of the so-called transmission type normally has an optical module either as a light projector or a light received set inside a single housing. If this optical module is structured as described above, therefore, the position-matching of its miniaturized semiconductor optical element and its lens part can be carried out easily and a small-sized photoelectric sensor can be obtained.

A photoelectric sensor according to another aspect of this invention may be characterized as including at least one of optical modules as described above as a light projector and at least one other of optical modules as described above as a light receiver.

A photoelectric sensor of the so-called reflection type normally includes inside a single housing two optical modules which are a light projector and a light receiver. Thus, even a photoelectric sensor with two or more optical modules can be made compact if the optical modules are structured according to this invention because the position-matching between its miniaturized semiconductor optical element and its lens part can be carried out easily and accurately.

A method of this invention for producing an optical module is characterized as comprising the steps of sealing a semiconductor optical element inside a transparent resin part, forming by injection molding a lens unit that includes a lens part and a planar part extending from this lens part and causing a principal surface part of the planar part to be adsorbed by an adsorbing means and thereby affixing the lens unit position-matched to a surface (upper surface) of the transparent resin part such that the lens part is positioned in a face-to-face relationship with the semiconductor optical element through the transparent resin part. By such a method, the lens unit can be indirectly supported and hence the position-matching can be effected easily.

In the production method as described above, it is preferable to form the planar part so as to have guide walls at edge parts opposite from the lens part and such that the lens unit is affixed to the transparent resin part so as to have the guide walls cover side surfaces of the transparent resin part because a rough position-matching is effected by the guide walls and the side surfaces that are continuous from the upper surface of the transparent resin part.

It is further preferable to form the lens unit such that the planar part has a thickness less than 0.6 mm and that the guide walls have a thickness of 0.6 mm or greater in the direction of the thickness of the planar part. The lens unit is preferably formed by striking eject pins towards the guide walls in the direction of the thickness of the planar part when the lens unit is removed from a mold. In this manner, the lens unit can be effectively removed from the mold after being formed by an injection molding method and hence the planar part can be made thinner and the optical module can be made smaller.

### BRIEF DESCRIPTION OF THE DRAWINGS

FIG. 1 is an exploded diagonal view of a light projector according to a first embodiment of this invention.

FIG. 2 is a sectional view of a portion of the light projector of FIG. 1 when it is assembled.

FIGS. 3-7 are schematic sectional views illustrating processes for producing the light projector of FIG. 1.

FIG. 8 is an exploded diagonal view of a light projector according to a second embodiment of this invention.

FIG. 9 is a diagonal view of the lens unit of the light projector of FIG. 8.

FIG. 10 is a sectional view of a portion of the light projector of FIG. 8 when it is assembled.

FIGS. 11-14 are schematic sectional views illustrating processes for producing the light projector of FIG. 8.

FIG. 15 is an exploded diagonal view of a light receiver according to a third embodiment of this invention.

FIG. 16 is a diagonal view of the lens unit of the light receiver of FIG. 15.

FIG. 17 is a sectional view of a portion of the light receiver of FIG. 15 when it is assembled.

FIG. 18 is a schematic diagram of a distance-setting type of photoelectric sensor incorporating a light receiver according to the third embodiment of this invention.

FIG. 19 is a sectional view of a portion of a light projector according to a fourth embodiment of this invention.

### DETAILED DESCRIPTION OF THE INVENTION

The invention is described next by way of examples wherein the invention is applied to a light projector and a light receiver of a photoelectric sensor as an optical module. In the examples that are described, like components are indicated by the same symbols and their descriptions will not be repeated.

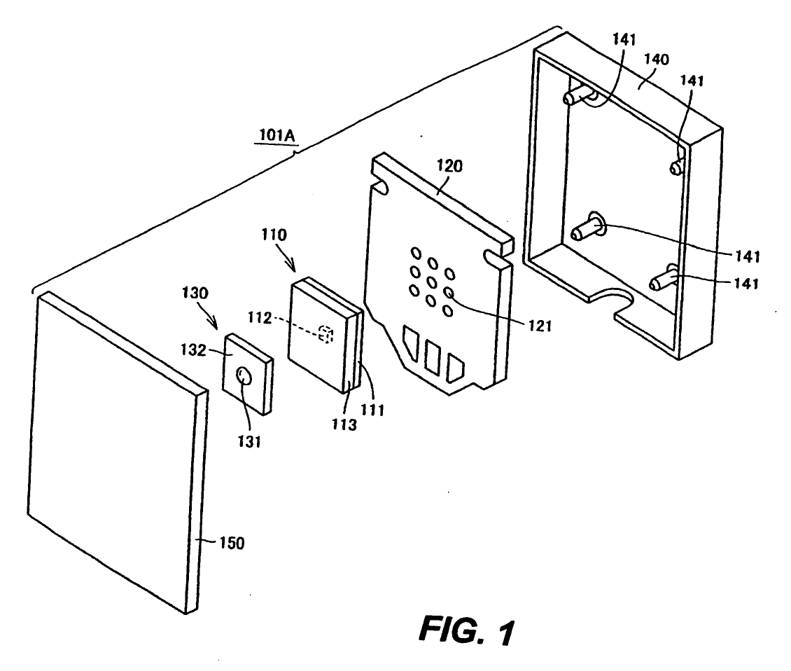

FIG. 1 is an exploded diagonal view of a light projector 101A as a first embodiment of this invention, and FIG. 2 is a sectional view of this light projector 101A when it is assembled. FIGS. 1 and 2 will be referenced next to explain the structure of this light projector 101A.

As shown in FIGS. 1 and 2, this light projector 101A according to the first embodiment of this invention comprises an IC package 110 in the form of CSP, a mounting substrate 120, a lens unit 130, a case 140 and a cap 150. The IC package 110 in the form of CSP includes an intermediate substrate 111, an LED 112 which is a semiconductor optical element and a transparent resin part 113. The LED 112 is bear-chip mounted on a surface (upper surface) of the intermediate substrate 111 such that its light projecting surface will face upward. The transparent resin part 113 is formed on the upper surface of the intermediate substrate 111 so as to cover the bear-chip mounted LED 112. In this way, the LED 112 is sealed in by the transparent resin part 113. Epoxy resin is preferable as the material of the transparent resin part 113. Components other than the LED 112 may be mounted to the surface of the transparent resin part 113.

The IC package 110 is mounted such that the back surface of its intermediate substrate 111 faces opposite the mounting substrate 120. Explained more in detail, a conductor pattern (not shown) formed on the back surface of the intermediate substrate 111 and another conductor pattern 121 formed on a surface (upper surface) of the mounting substrate 120 are joined together with solder (not shown) such that the electrical circuit on the intermediate substrate 111 and the electrical circuit on the mounting substrate 120 are electrically connected and the IC package 110 comes to be securely affixed to the mounting substrate 120. It goes without saying that the mounting substrate 120 may have components other than the IC package 110 mounted thereto.

The lens unit 130 is position-matched and attached to the upper surface 113a of the transparent resin part 113 of the IC package 110. The lens unit 130 includes a lens part 131 serving as the projection lens and a planar part 132 that extends sideways from the lens part 131, being formed in a substantially planar form as a whole with the projection lens at the center. In other words, it is formed such that the lens part 131 is surrounded by the planar part 132 that protrudes sideways from the lens part 131 in all sideway directions, extending along the upper surface 113a of the transparent resin part 113 of the IC package 110. The lens part 131 is made of a material such as polycarbonate resin or acryl resin, being preferably formed by injection molding. An adhesive 118 containing a resin material that hardens by ultraviolet light is used to fasten the lens unit 130 to the upper surface 1 13a of the transparent resin part 113.

The lens unit 130 is fastened to the upper surface 113a of the transparent resin part 113 such that its lens part 131 is position-matched with respect to the LED 112, or that the optical axis of the LED 112 and that of the lens part 131 coincide with each other.

The mounting substrate 120 is fastened so as to be contained inside the case 140 which is box-shaped with its upper surface open. Explained more in detail, it is fastened so as to be position-matched by means of position-matching pins 141 provided on the bottom surface of the case 140. The cap 150 is further attached to the case 140, serving to close the upper opening of the case 140. It is necessary that at least a central part of the cap 150 be made of a transparent material such that light from the LED 112 passing through the lens part 131 can be projected out of the light projector 101A. Polycarbonate resin, acryl resin and polyarylate resin materials are appropriate as a material for the cap 150.

According to the embodiment shown in FIG. 2, the light projector 101A is so designed that the thickness t1 of the planar part 132 in the direction perpendicular to the upper surface 113a of the transparent resin part 113 is 0.6 mm or greater and smaller than the maximum thickness T1 of the lens part 131 in the same direction. The thickness t1 is preferably 1.0 mm or less.

The reason for requiring t1 to be at least 0.6 mm is that the eject pins will not penetrate the planar part 132 of the lens unit 130 when the lens unit 130 is formed by injection molding and is being removed from the mold. The reason for making t1 less than T1 is that the light projector 101A can be made thinner by reducing the distance between the cap 150 and the lens part 131 of the lens unit 131 as much as possible. The reason for preferably making t1 equal to or less than 1.0 mm is that if it were greater than 1.0 mm, it would be possible to carry out the aforementioned position-matching by holding the side surfaces of the lens part 131 without the presence of the planar part 132. The maximum thickness T1 is one of the parameters for determining the optical characteristics of the light projector 101A. There is no particular limitation thereon.

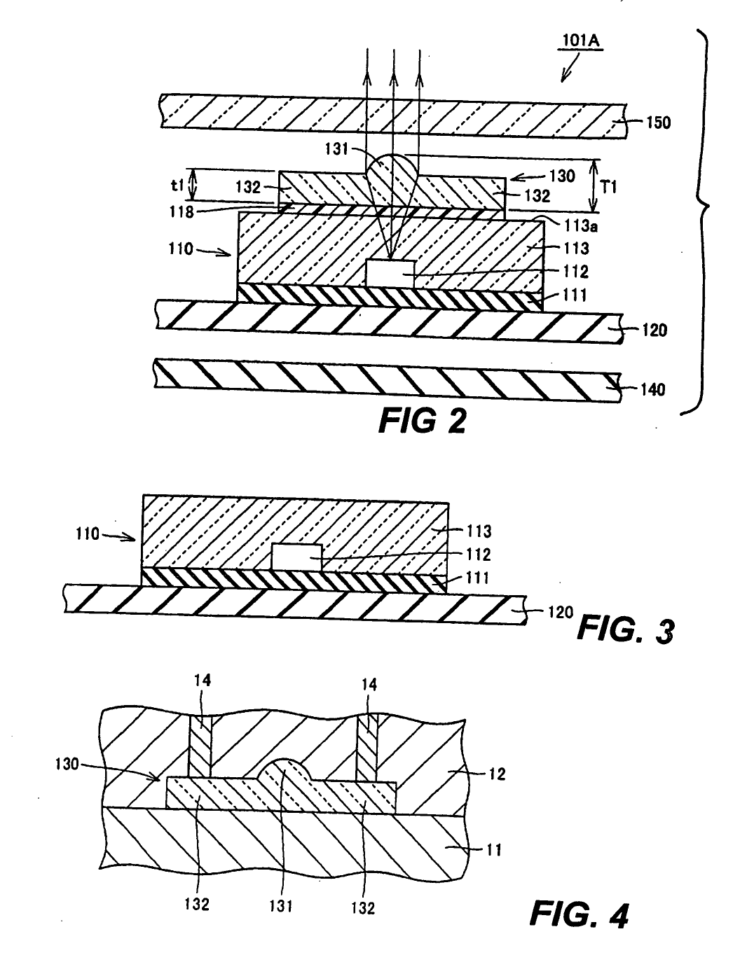

A method of producing the light projector 101A will be described next with reference to FIGS. 3-7 which are schematic sectional views each illustrating one of the production processes.

To start, the LED 112 is bear-chip mounted to the upper surface of the intermediate substrate 111, as shown in FIG. 3. Next, the transparent resin part 113 is formed on the intermediate substrate 111 so as to seal in the bear-chip mounted LED 112. The IC package 110 in the form of CSP is thus prepared and is affixed to the upper surface of the mounting substrate 120.

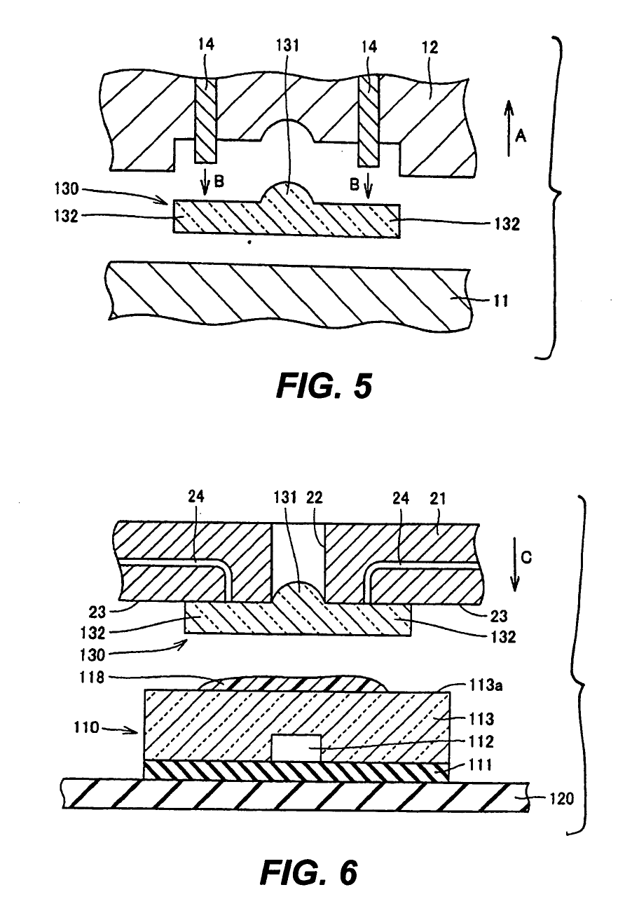

Aside from the process described above with reference to FIG. 3, the lens unit 130 is separately prepared by injection molding, as shown in FIGS. 4 and 5. Molds 11 and 12 are prepared and combined, and a molten transparent resin material is poured into the space formed in between and is hardened to form the lens unit 130. Since the lens unit 130 thus obtained is a very small component, its removal from the molds 11 and 12 is a problem. According to the method of this invention, mold 11 is separated from mold 12 as shown in FIG. 5 in the direction of arrow A and at the same time when the eject pins 14 are struck towards the planar part 132 in the direction of arrows B such that the lens unit 130 can be smoothly separated from the molds 11 and 12. This is made possible because the thickness t1 of the planar part 132 of the lens unit 130 is limited to be 0.6 mm or greater, as explained above. Thus, the lens unit 130 is taken out of the mold 12 without being damaged as the eject pins 14 are struck.

Next, a specified amount of the adhesive 118 containing a resin material that is ultraviolet-hardenable is applied to the upper surface 113a of the transparent resin part 113 of the IC package 110 affixed to the mounting substrate 120 and, while the lens unit 130 produced by injection molding as explained above is held by suction by means of a suction head 21, the suction head 21 is lowered in the direction of arrow C, as shown in FIG. 6. The lens unit 130 is adsorbed onto the suction head 21 with its lens part 131 inserted into an opening 22 formed on the adsorption surface 23 of the suction head 21 and the upper surface of its planar part 132 positioned so as to contact this adsorption surface 23 of the suction head 21 where suction tubes 24 open.

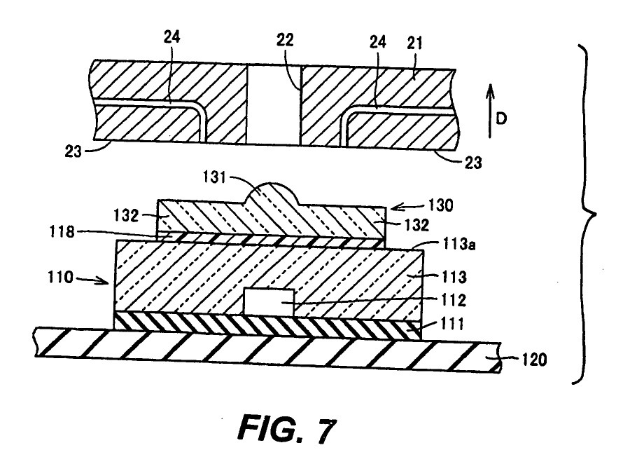

Next, as shown in FIG. 7, the lens part 131 of the lens unit 130 is position-matched with respect to the LED 112 that is sealed inside the IC package 110 such that the optical axes of the LED 112 and the lens part 131 will become coaxial, and the adhesive 118 is exposed to ultraviolet light while this position-matched condition is maintained such that the adhesive 118 is hardened. Thus, the lens unit 130 becomes affixed to the upper surface 113a of the transparent resin part 113 of the IC package 110. A device for adjusting an optical axis disclosed in aforementioned Japanese Patent Publication Tokkai 2-188972 may be used for this position-matching process. After the lens unit 130 is thus directly affixed to the IC package 110, the adsorption by the suction head 21 is released and the suction head 21 is removed in the direction of arrow D.

Next, the mounting substrate 120 having mounted thereto the IC package 110 with the lens unit 130 affixed thereto is positioned and affixed to the case 140, and the cap 150 is attached to this case 140 to complete the light projector 101A structured as shown in FIG. 2.

As the light projector 101A is produced as described above, the position-matching process of the lens part 131 with respect to the LED 112 can be carried out easily although the lens part 131 is made small and thin because the lens part 131 is indirectly supported by the suction head 21 to adsorb the upper surface of the planar part 132 of the lens unit 130 that includes the lens part 131. Thus, the light projector 101A can be produced with high productivity and hence inexpensively although its lens part 131 is made smaller and thinner.

Since the planar part 132 is formed so as to surround the lens part 131 and to extend sideways, the area of the upper surface of the planar part 132 can be made sufficiently large and hence the suction head 21 can reliably support the lens unit 130 and that the production efficiency can be maintained high.

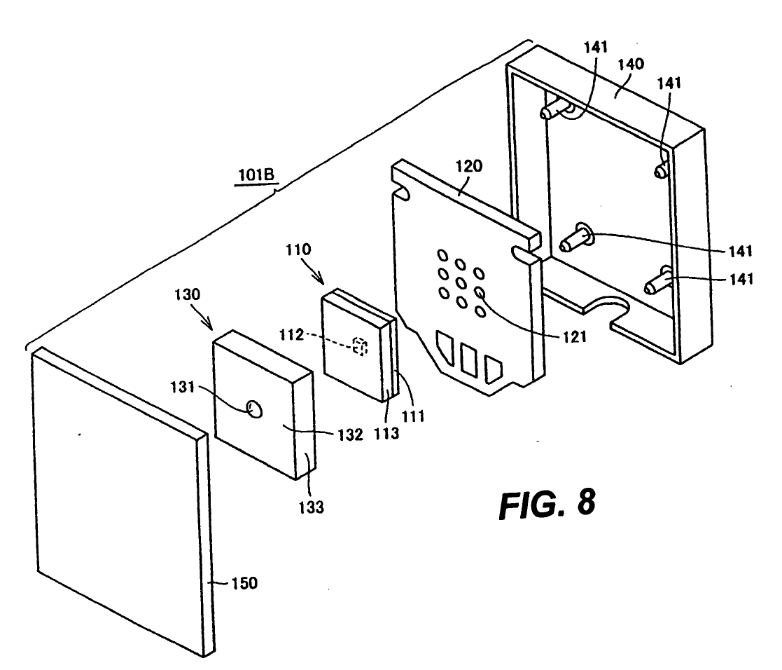

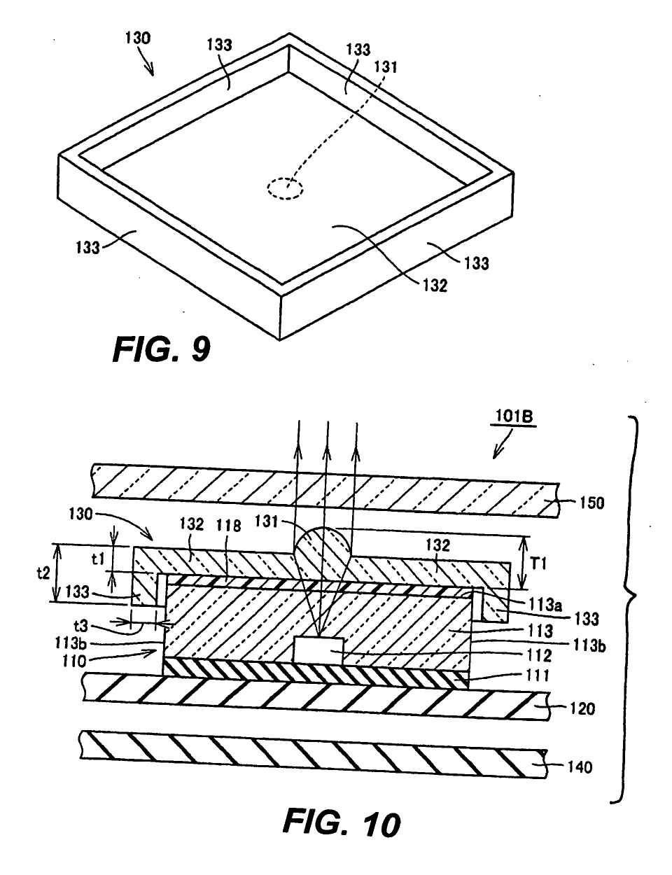

FIG. 8 is an exploded diagonal view of a light projector 101B according to a second embodiment of this invention and FIG. 9 is a diagonal view for explaining the structure of this light projector 101B more in detail. FIG. 10 is a sectional view of a portion thereof after this light projector 101B has been assembled.

As shown in FIGS. 8 and 10, the light projector 101B according to the second embodiment of this invention comprises, like the light projector 101A according to the first embodiment of the invention described above, an IC package 110 in the form of CSP, a mounting substrate 120, a lens unit 130, a case 140 and a cap 150. The shape of this lens unit 130 is different from the corresponding unit of the light projector 101A of the first embodiment.

As shown in FIGS. 8 and 10, the lens unit 130 of the light projector 101B includes a lens part 131 serving as the projection lens and a planar part 132 that extends sideways from the lens part 131. The planar part 132 has guide walls 133 at edge parts on a side opposite from the lens part 131. In other words, as shown in FIG. 9, the lens unit 130 of the light projector 101B according to the second embodiment of the invention is of a box-shape with an open lower surface, the projection lens being at a center part of its principal surface. The planar part 132 is formed so as to extend along the upper surface 113a of the transparent resin part 113 of the IC package 110, and the guide walls 133 extend downward along a side surface 113b of the transparent resin part 113. The lens part 131 is made of a material such as polycarbonate resin or acryl resin, being preferably formed by injection molding.

As shown in FIG. 10, the lens unit 130 is affixed by means of the adhesive 118 to the upper surface 113a of the transparent resin part 113 of the IC package 110 formed as CSP and containing the LED 111 inside such that the upper surface 113a of the transparent resin part 113 comes to be covered by the principal surface of the lens unit 130 including the lens part 131 and the planar part 132 and the upper portions of the side surfaces 113b of the transparent resin part 113 come to be covered by the guide walls 133.

The lens unit 130 is affixed to the upper surface 113a of the transparent resin part 113 with its lens part 131 position-matched with respect to the LED 112 such that the optical axes of the LED 112 and the lens part 131 coincide with each other.

According to the second embodiment of the invention, the light projector 101B is so designed that the thickness t1 of the planar part 132 in the direction perpendicular to the upper surface 113a of the transparent resin part 113 is less than 0.6 mm, preferably less than 0.5 mm and even more preferably less than 0.4 mm, and smaller than the maximum thickness T1 of the lens part 131 in the same direction. The width (in the direction perpendicular to the upper surface 113a of the transparent resin part 113) t2 of the guide walls 133 is 0.6 mm or greater, and the thickness (in the direction perpendicular to the side surface 113b of the transparent resin part 113) t3 of the guide walls 133 is substantially the same as t1.

The reason for requiring t1 to be less than 0.6 mm is that the planar part 132 may be made thinner than 0.6 mm as the lens part 131 is made smaller. The reason for making t1 less than T1 is that the light projector 101B can be made thinner by setting the cap 150 and the lens part 131 of the lens unit 130 as close to each other as possible. For forming the lens unit 130 by injection molding in such a situation, the lens unit 130 must be 0.6 mm or more in thickness such that eject pins will not penetrate and damage the lens unit 130 as a molded product when it is removed from the mold. If eject pins strike the lens part 131 thicker than the planar part 132, however, the surface of the lens part 131 may be damaged, and since light scattering takes place at such damaged portions, there is a high probability of adversely affecting the characteristic as a light projector. This is why the width t2 of the guide walls is selected to be 6 mm or greater and the guide pins are made to strike thereon. This aspect of the invention will be further described in detail below.

The reason for making t1 and t3 substantially equal is that the molten resin material can circulate inside the mold more easily at the time of the injection molding and the lens unit 130 can be formed in an improved manner. The maximum thickness T1 of the lens part 131 is one of the parameters for determining the optical characteristics of the light projector 101B. There is no particular limitation thereon.

In the above, if the width t2 of the guide walls 133 is made 1.0 mm or greater, it becomes possible to hold (or particularly by adsorption) the lens unit 130 from its sides. If this is done, therefore, it means an increase in the degree of freedom in the handling at the time of the position-matching of the lens unit 130 with respect to the LED 112.

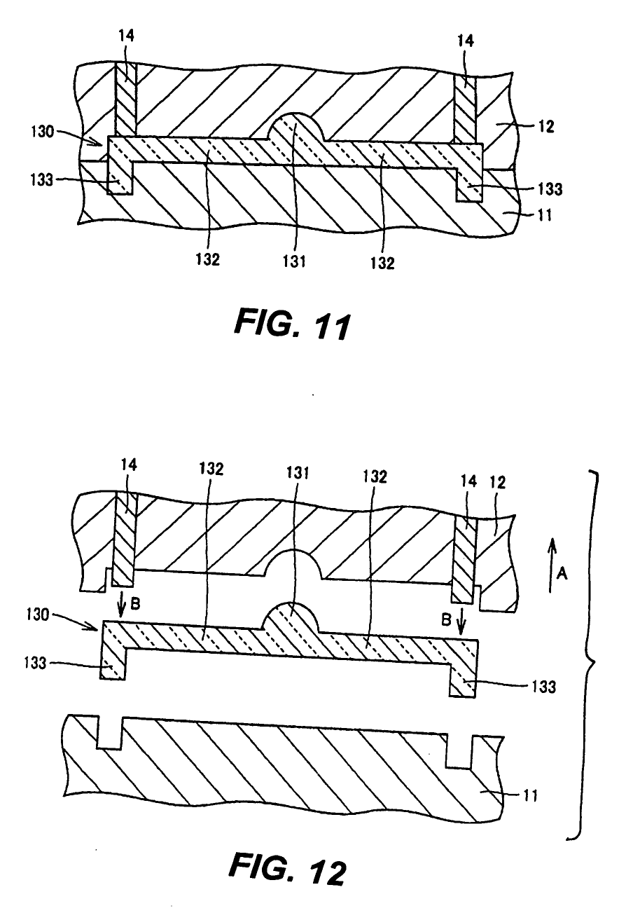

A method of producing the light projector 101B will be described next with reference to FIGS. 11-14 which are schematic sectional views each illustrating one of the production processes.

To start, as in the case of the first embodiment of the invention, the IC package 110 in the form of CSP is prepared and is affixed to the upper surface of the mounting substrate 120.

Aside from the process described above, the lens unit 130 is separately prepared by injection molding, as shown in FIGS. 11 and 12. Molds 11 and 12 are prepared and combined, and a molten transparent resin material is poured into the space formed in between and is hardened to form the lens unit 130. Since the lens unit 130 thus obtained is a very small component, its removal from the molds 11 and 12 is a problem. According to the method of this invention, mold 11 is separated from mold 12 as shown in FIG. 12 in the direction of arrow A and at the same time the eject pins 14 are struck towards the guide walls 133 in the direction of arrows B such that the lens unit 130 can be smoothly separated from the molds 11 and 12. This is made possible because the width t2 of the guide walls 133 of the lens unit 130 is made to be 0.6 mm or greater, as explained above. Thus, the lens unit 130 is taken out of the mold 12 without being damaged as the eject pins 14 are struck towards the guide walls 133.

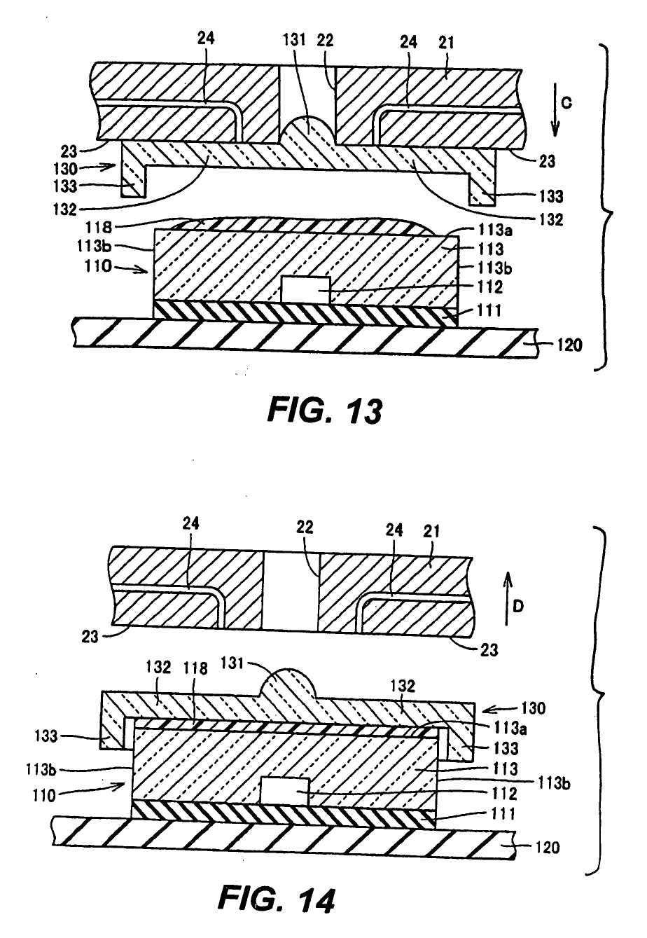

Next, a specified amount of the adhesive 118 containing a resin material that is ultraviolet-hardenable is applied to the upper surface 113a of the transparent resin part 113 of the IC package 110 affixed to the mounting substrate 120 and, while the lens unit 130 produced by injection molding as explained above is held by suction by means of a suction head 21, the suction head 21 is lowered in the direction of arrow C, as shown in FIG. 13. The lens unit 130 is adsorbed onto the suction head 21 with its lens part 131 inserted into an opening 22 formed on the adsorption surface 23 of the suction head 21 and the upper surface of its planar part 132 positioned so as to contact this adsorption surface 23 of the suction head 21 where suction tubes 24 open. The box-shaped lens unit 130 is attached so as to cover the transparent resin part 113 such that the guide walls 133 will be opposite the side surfaces 113b of the transparent resin part 113.

Next, as shown in FIG. 14 and as explained above regarding the first embodiment, the lens part 131 of the lens unit 130 is position-matched with respect to the LED 112 that is sealed inside the IC package 110 such that the optical axes of the LED 112 and the lens part 131 will become coaxial, and the adhesive 118 is exposed to ultraviolet light while this position-matched condition is maintained such that the adhesive 118 is hardened. Thus, the lens unit 130 becomes affixed to the upper surface 113a of the transparent resin part 113 of the IC package 110. After the lens unit 130 is thus directly affixed to the IC package 110, the adsorbing force by the suction head 21 is released and the suction head 21 is removed in the direction of arrow D. If the width t2 of the guide walls 133 is 1.0 mm or greater, the suction head 21 may be contacted sideways to the lens unit 130 to support it by adsorption.

The processes thereafter to complete the light projector 101B structured as shown in FIG. 10 are as described above regarding the first embodiment.

Advantages of the second embodiment over the first embodiment include the following. Firstly, even if the lens part 131 is made still smaller, the lens unit 130 can still be formed by injection molding because the molded object can be safely released from the mold by pushing it through the eject pins. Secondly, since a rough position-matching can be effected by the guide walls 133 and the side surfaces 113b of the transparent resin part 113, the position-matching of the lens part 131 with respect to the LED 112 becomes easier. Thirdly, since the excess portion of the adhesive 118 is guided by the guide walls 133 and the planar part 132 to the side of the side walls 113b of the transparent resin part 113, it can be prevented from getting attached to the suction head or the lens part 131. Thus, the production efficiency can be maintained high even if the lens part 131 is further made smaller and thinner.

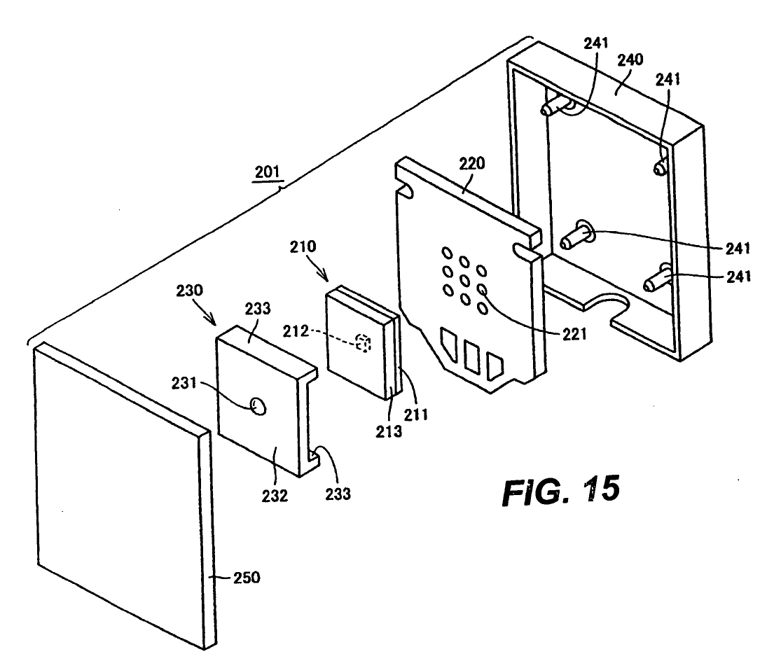

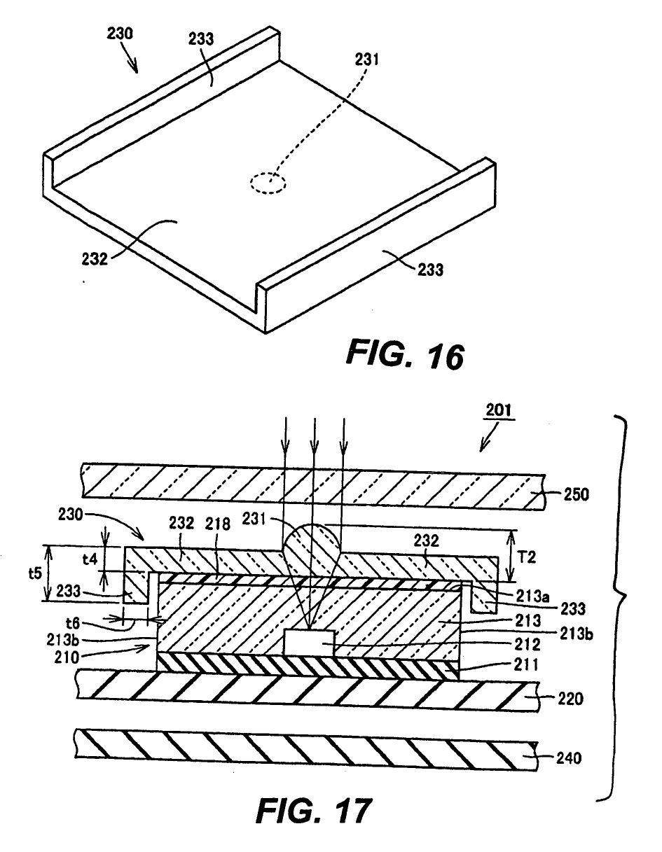

FIG. 15 is an exploded diagonal view of a light receiver 201 according to a third embodiment of this invention and FIG. 16 is a diagonal view for explaining the structure of this light receiver 201 more in detail. FIG. 17 is a sectional view of a portion thereof after this light receiver 201 has been assembled. In what follows, these figures are referenced to explain the structure of this light receiver. Since the method of its production is similar to that of the light projector 101B according to the second embodiment of the invention, it will not be described repetitiously.

As shown in FIGS. 15 and 17, the light receiver 201 according to the third embodiment of this invention comprises an IC package 210 in the form of CSP, a mounting substrate 220, a lens unit 230, a case 240 and a cap 250.

The IC package 210 in the form of CSP includes an intermediate substrate 211, a PD which is a semiconductor optical element and a transparent resin part 213. The PD 212 is bear-chip mounted on the upper surface of the intermediate substrate 211 such that its light receiving surface will face upward. The transparent resin part 213 is formed on the upper surface of the intermediate substrate 211 so as to cover the bear-chip mounted PD 212. In this way, the PD 212 is sealed in by the transparent resin part 213. Epoxy resin is preferable as the material of the transparent resin part 213. Components other than the PD 212 may be mounted to the surface of the transparent resin part 213.

The IC package 210 is mounted such that the back surface of its intermediate substrate 211 faces opposite the mounting substrate 220. Explained more in detail, a conductor pattern (not shown) formed on the back surface of the intermediate substrate 211 and another conductor pattern 221 formed on the upper surface of the mounting substrate 220 are joined together with solder (not shown) such that the electrical circuit on the intermediate substrate 211 and the electrical circuit on the mounting substrate 220 are electrically connected and the IC package 210 comes to be securely affixed to the mounting substrate 220. It goes without saying that the mounting substrate 220 may have components other than the IC package 210 mounted thereto.

The lens unit 203 is position-matched and attached to the upper surface 213a of the transparent resin part 213 of the IC package 210. The lens unit 230 includes a lens part 231 serving as the light receiving lens and a planar part 232 that extends sideways from the lens part 231. Guide walls 233 are further formed from a pair of mutually opposite edge parts of the planar parts away from the lens part 231. Thus, as shown in FIG. 16, the lens unit 230 of this light receiver 201 is box-shaped as a whole with an open bottom surface and a pair of open side surfaces, having the light receiving lens at the center of its principal surface. The planar part 232 extends along the upper surface 213a of the transparent resin part 213, and the guide walls 233 extends downward along the side surfaces of the transparent resin part 213 from side edges of the planar part 232. The lens part 231 is made of a material such as polycarbonate resin or acryl resin, being preferably formed by injection molding. An adhesive 218 containing a resin material that hardens by ultraviolet is used to fasten the lens unit 230 to the upper surface 213a of the transparent resin part 213.

The lens unit 230 is fastened to the upper surface 213a of the transparent resin part 213 such that its lens part 231 is position-matched with respect to the PD 212, or that the optical axis of the PD 212 and that of the lens part 231 coincide with each other.

The mounting substrate 220 is fastened so as to be contained inside the case 240 which is box-shaped with its upper surface open. Explained more in detail, it is fastened so as to be position-matched by means of position-matching pins 241 provided on the bottom surface of the case 240. The cap 250 is further attached to the case 240, serving to close the upper opening of the case 240. It is necessary that at least a central part of the cap 250 be made of a transparent material such that light passing through the lens part 231 to be received by the PD 212 can reach the lens part 231 from the exterior of the light receiver 201. Polycarbonate resin, acryl resin and polyarylate resin materials are appropriate for the cap 250.

According to the embodiment shown in FIG. 17, the light receiver 201A is so designed that the thickness t4 of the planar part 232 in the direction perpendicular to the upper surface 213a of the transparent resin part 213 is less than 0.6 mm, preferably less than 0.5 mm and more preferably less than 0.4 mm and smaller than the maximum thickness T2 of the lens part 231 in the same direction. The width (in the direction perpendicular to the upper surface 213a of the transparent resin part 213) t5 of the guide walls 233 is 0.6 mm or greater, and the thickness (in the direction perpendicular to the side surface 213b of the transparent resin part 213) t6 of the guide walls 233 is substantially the same as t4.

The reason for requiring t4 to be less than 0.6 mm is that the planar part 232 may be made thinner than 0.6 mm as the lens part 231 is made smaller. The reason for making t4 less than T2 is that the light receiver 201 can be made thinner by setting the cap 250 and the lens part 231 of the lens unit 230 as close to each other as possible. For forming the lens unit 230 by injection molding in such a situation, the lens unit 230 must be 0.6 mm or more in thickness such that eject pins will not penetrate and damage the lens unit 230 as a molded product when it is removed from the mold. If eject pins strike the lens part 231 thicker than the planar part 232, however, the surface of the lens part 231 may be damaged, and since light scattering takes placed at such damaged portions, there is a high probability of adversely affecting the characteristic as a light projector. This is why the width t5 of the guide walls is selected to be 6 mm or greater and the guide pins are made to strike thereon. Details of this aspect of the invention are similar to those explained above regarding the second embodiment of the invention.

The reason for making t4 and t6 substantially equal is such that the molten resin material can circulate inside the mold more easily at the time of the injection molding and the lens unit 230 can be formed in an improved manner. The maximum thickness T2 of the lens part 231 is one of the parameters for determining the optical characteristics of the light receiver 201. There is no particular limitation thereon.

In the above, if the width t5 of the guide walls 233 is made 1.0 mm or greater, it becomes possible to hold (or particularly by adsorption) the lens unit 230 from its sides. If this is done, therefore, it means an increase in the degree of freedom in the handling at the time of the position-matching of the lens unit 230 with respect to the PD 212.

With the light receiver 201 thus structured, effects similar to those obtainable by the light projectors 101A and 101B according to the first and second embodiments of this invention can be obtained. In other words, light receivers of a high quality can be produced inexpensively and with a high productivity even if the lens part 231 is made small and thin. Moreover, since the transparent resin part 231 is sandwiched by a pair of guide walls 233, the position-matching of the lens unit 230 on the upper surface 213a of the transparent resin part 213 is required only in one direction and hence the work of position-matching becomes significantly simplified.

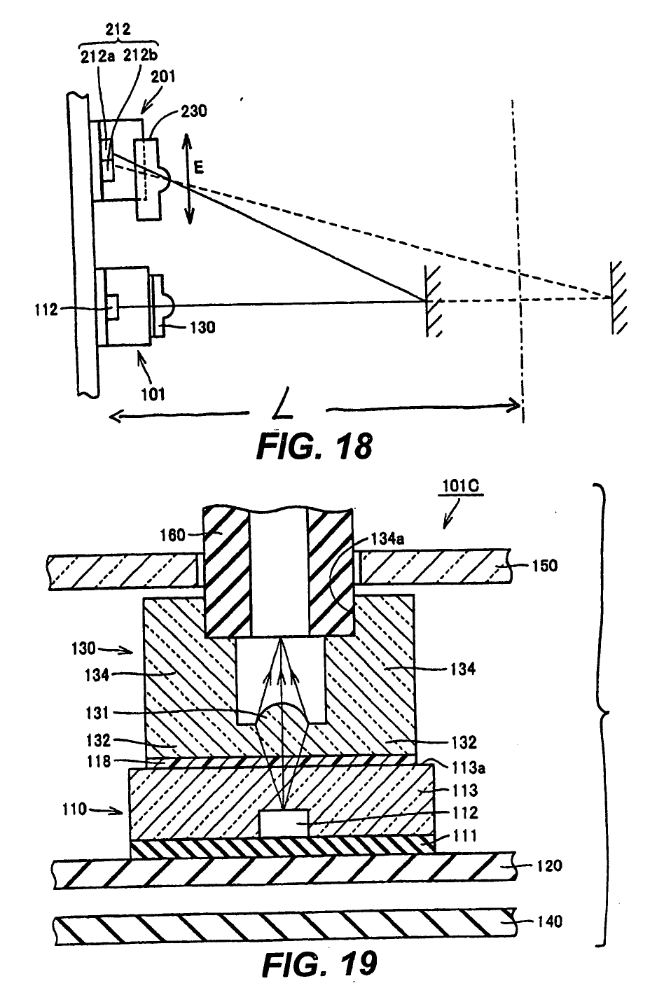

FIG. 18 shows a situation wherein a light receiver of this invention is used in a distance-setting type of photoelectric sensor because the light receiver 201 as described above is particularly useful when used in this type of photoelectric sensor.

A photoelectric sensor of the distance-setting type makes use of position detecting elements such as a divided photodiode or position sensitive diodes (PSD) and detects an object in front of a specified reference position by calculating the difference between output signals from such elements and comparing the calculated difference with a specified threshold value. It is usually set such that objects at a larger distance than the aforementioned reference position will not be detected. It now goes without saying that the accuracy in positioning of the light projection and receiving elements (light projector and receiver) in the production of such a photoelectric sensor of the distance-setting type is extremely important.

FIG. 18 shows a photoelectric sensor of the distance-setting type with a light projector 101 and a light receiver 201 placed near each other. The PD 212 of the light receiver 201 is divided into a first light receiving part 212a and a second light receiving part 212b such that light from the light projector 101, after being reflected by an object at a distance shorter than a specified value L, will be received by the first light receiving part 212a and that light from the light projector 101, after being reflected by an object at a distance greater than the specified value L, will be received by the second light receiving part 212b.

The light projector 101 is adapted to send a light beam through the light projecting lens unit 130 to a detection area. The light receiving lens unit 230 and the divided photodiode 212 are positioned at specified angles with respect to this light beam. Explained more in detail, the light projector and the light receiver 201 are structured and positioned such that the line connecting the centers of the lens unit 230 and the divided PD 212 will cross the optical axis of the light projector 101 at a set position that is at the specified distance L.

Signal processing for the distance-setting photoelectric sensor is carried out by means of a signal processing circuit (not shown) mounted to the mounting substrate 220. One end of each of the first and second light receiving parts 212a and 212b of the PD 212 is connected to an I/V converter (not shown) adapted to convert the current received from the corresponding light receiving part 212a or 212b of the PD 212 into a voltage signal. The output voltage signals are each amplified by means of an amplifier (not shown) and transmitted to a differential circuit (not shown) for generating therefrom a differential signal. The differential signal is transmitted to a comparator circuit (not shown) to be compared with a specified threshold value. The comparator circuit is adapted to determine whether the target object which reflected light is at a distance shorter or longer than the specified distance L, depending upon whether the differential signal is positive or negative.

If the light receiver 201 is structured according to this invention, the lens unit 231 may be moved in the direction of arrow E according to the specified distance L for its position-matching with respect to the transparent resin part 213 which is sandwiched between the pair of guide walls 233. In other words, the position-matching can be effected easily and hence photoelectric sensors of the distance-setting type can be produced easily according to this invention.

It now goes without saying that the present invention has merits also regarding other kinds of reflection-type photoelectric sensors. Optical characteristics of a reflection-type photoelectric sensor are determined by its light projecting and receiving parts respectively comprising a light projector and a light receiver. Many of the problems related to fluctuations with the prior art technology can be eliminated if light projector and receiver of this invention are used in the light projecting and receiving parts of a reflection-type photoelectric sensor and adjustments are made according to this invention such that they each will have required optical characteristics. It also becomes possible to stably and reliably produce reflection-type photoelectric sensors by eliminating changes in the characteristics caused in their assembly process, as well as to eliminate the effects of changes in the environment in which they are used.

FIG. 19 is a sectional view of a portion of a light projector 101 C according to a fourth embodiment of this invention, having an optical fiber 160 for leading light from an LED 112 to a target object to be detected through the lens part 131 serving as the light projecting lens.

The lens unit 130 of this light projector 101C includes the lens part 131, a planar part 132 which extends sideways from the lens part 131 and a wall part 134 which protrudes upward from the planar part 132. The planar part 132 extends along the upper surface 113a of the transparent resin part 113 of the IC package 110, and the wall part 134 extends in the upward direction away from the transparent resin part 113. The wall part 134 has an indentation 134a at a position facing the lens part 131, formed by indenting the upper surface of the wall part 134 in the direction toward the lens part 131. An end part of the optical fiber 160 is connected and fastened to this indentation 134a.

With the light projector 101C thus formed, the optical fiber 160 can be easily affixed to the lens unit 130 and hence a light projector having an optical fiber attached to it can be produced easily and inexpensively. Since the optical fiber can be position-matched easily with respect to the lens part 131, a light projector of a high quality can thus be obtained.

Although the invention has been described above as embodied in light projectors and receivers, aspects embodied in a light projector may be embodied in a light receiver and aspects embodied in a light receiver may equally be embodied in a light projector. It also goes without saying that those illustrated aspects of the invention can be applied to many different kinds of optical modules other than light projectors and receivers, such as optical communication devices. In summary, the illustrated examples are not intended to limit the scope of the invention.

What is claimed is:

1. An optical module comprising:
a semiconductor optical element;
a transparent resin part that seals in said semiconductor optical element; and
a lens unit affixed to an upper surface of said transparent resin part;
wherein said lens unit includes:
a lens part that is disposed facing opposite said semiconductor optical element through said transparent resin part; and
a planar part that extends from said lens part along said upper surface of said transparent resin part.

2. The optical module of claim 1 wherein said planar part completely surrounds said lens part and extends from the entire circumference of said lens part.

3. The optical module of claim 1 wherein said planar part has guide walls on edge parts away from said lens part, said guide walls extending so as to cover side surfaces that connect to said upper surface of said transparent resin part.

4. The optical module of claim 3 wherein said planar part includes a pair of mutually oppositely extending portions from said lens part;
wherein said guide walls extend from end parts of said mutually oppositely extending portions; and
wherein said guide walls extend so as to cover mutually opposite side surfaces that connect to said upper surface of said transparent resin part.

5. The optical module of claim 1 wherein the thickness of said planar part perpendicular to said upper surface of said transparent resin part is 0.6 mm or greater and is equal to or less than the maximum thickness of said lens part.

6. The optical module of claim 3 wherein the thickness of said planar part perpendicular to said upper surface of said transparent resin part is less than 0.6 mm; and
wherein the width of said guide wall in the direction perpendicular to said upper surface of said transparent resin part is 0.6 mm or greater.

7. The optical module of claim 3 wherein the thickness of said planar part perpendicular to said upper surface of said transparent resin part is substantially the same as the thickness of said guide walls in the direction perpendicular to said side surfaces.

8. The optical module of claim 1 wherein the maximum thickness of the portion of said planar part on said transparent resin part in the direction perpendicular to said upper surface of said transparent resin part is 1.0 mm or less.

9. The optical module of claim 1 wherein said planar part includes a wall part protruding in opposite direction away from said transparent resin part;
wherein said wall part has an indentation at a position opposite said lens part, indenting in the direction towards said lens part; and
wherein an optical fiber has one end inserted to said indentation such that said optical fiber is affixed to said wall part with said one end facing said lens part.

10. The optical module of claim 3 wherein said planar part includes a wall part protruding in opposite direction away from said transparent resin part;
wherein said wall part has an indentation at a position opposite said lens part, indenting in the direction towards said lens part; and
wherein an optical fiber has one end inserted to said indentation such that said optical fiber is affixed to said wall part with said one end facing said lens part.

11. The optical module of claim 3 wherein said lens unit comprises polycarbonate or acryl resin as principal material.

12. A photoelectric sensor including an optical module according to claim 1 as a light projector or as a light receiver.

13. The photoelectric sensor of claim 12, including an optical module according to claim 1 as a light projector and another optical module according to claim 1 as a light receiver.

14. A photoelectric sensor comprising:
a light projecting part having a light projecting element for projecting a light beam to a detection area;
a light receiving element;
a transparent resin part that seals in said light receiving element; and
a lens unit affixed to an upper surface of said transparent resin part, said lens unit including:
a lens part that is disposed facing opposite said light receiving element through said transparent resin part; and
a planar part that extends from said lens part along said upper surface of said transparent resin part;
wherein said photoelectric sensor serves to obtain by triangulation a physical quantity that is equivalent to the distance to a target object for detection, based on light receiving position by said light receiving element, and to determine the distance to said target object by comparing said physical quantity with a threshold value.

15. The photoelectric sensor of claim 14 wherein said planar part completely surrounds said lens part and extends from the entire circumference of said lens part;
wherein said planar part has guide walls on edge parts away from said lens part; and
wherein said guide walls extend so as to cover side surfaces that connect to said upper surface of said transparent resin part.

16. A photoelectric sensor comprising:
a light projecting element;
a light receiving element;
a transparent resin part that seals in said light projecting element; and
a lens unit affixed to an upper surface of said transparent resin part, said lens unit including:
a lens part that is disposed facing opposite said light projecting element through said transparent resin part; and
a planar part that extends from said lens part along said upper surface of said transparent resin part;
wherein said photoelectric sensor serves to obtain by triangulation a physical quantity that is equivalent to the distance to a target object for detection, based on light receiving position by said light receiving element, and to determine the distance to said target object by comparing said physical quantity with a threshold value.

17. The photoelectric sensor of claim 16 wherein said planar part completely surrounds said lens part and extends from the entire circumference of said lens part;
wherein said planar part has guide walls on edge parts away from said lens part; and
wherein said guide walls extend so as to cover side surfaces that connect to said upper surface of said transparent resin part.

18. A method of producing an optical module, said method comprising the steps of:
sealing a semiconductor optical element inside a transparent resin part;
forming by injection molding a lens unit that includes a lens part and a planar part extending from said lens part; and
causing a principal surface part of said planar part to be adsorbed by an adsorbing means and thereby affixing said lens unit position-matched to an upper surface of said transparent resin part such that said lens part is positioned in a face-to-face relationship with said semiconductor optical element through said transparent resin part.

19. The method of claim 18 wherein said planar part is formed so as to have guide walls at edge parts opposite from said lens part and wherein said lens unit is affixed to said transparent resin part such that said guide walls cover side surfaces of said transparent resin part, said side surfaces being continuous with said upper surface.

20. The method of claim 19 wherein said lens unit is formed such that said planar part has a thickness less than 0.6 mm and that said guide walls have a thickness of 0.6 mm or greater in the direction of said thickness of said planar part; and wherein the step of forming said lens unit includes the step of striking eject pins towards said guide walls in the direction of said thickness of said planar part when said lens unit is removed from a mold.
